(19) United States
(12) Patent Application Publication
(10) Pub. No.: US 2015/0208532 A1
(43) Pub. Date: Jul. 23, 2015

(54) Methods and Systems for Organizing Electrical Appliances

(71) Applicant: SSK LLC, Houston, TX (US)

(72) Inventor: Soroush Esfandiari, Houston, TX (US)

(73) Assignee: SSK LLC, Houston, TX (US)

(21) Appl. No.: 14/076,320

(22) Filed: Jan. 22, 2014

(51) Int. Cl. H05K 5/02

(52) U.S. Cl. CPC H05K 5/0247; H05K 5/0217; H05K 5/0239

(57) ABSTRACT

A method and system for efficiently storing and using wired appliances is disclosed. A body of the wired appliance organizer includes a first portion and a second portion and is configurable in an open position and a closed position. A holder is disposed within a first portion of the body and a reel is disposed within the second portion of the body. The reel comprises an electrical outlet and a power supply wire. The power supply wire electrically couples the electrical outlet to a main power supply line. A power supply wire from an electrical device is directed into the body through the inlet.

The present application claims priority to Provisional Application Ser. No. 61/789,086 which was filed on Mar. 14, 2013, and is incorporated by reference herein in its entirety.

### BACKGROUND

The present invention is generally directed to an improved method and system for organizing electrical appliances and more specifically, to a method and system for efficiently storing and using wired appliances.

With the increasing number of appliances often used at homes and businesses, it is important to efficiently use limited space and ensure that the wires from the different appliances are maintained in an organized manner.

For instance, at a hair salon, a hair dresser may have to use a number of different devices such as, for example, a hair dryer, a hair straightener, or a curling iron. Each of these devices needs to be connected to an outlet. Typically, a hair dresser connects each device to an outlet and places them in a drawer or on a work table. As each device is repeatedly used and put back in its place, the wires from the different devices often become tangled. Moreover, this lack of organization clutters the work spaces creating an unattractive work environment. In addition, detangling the wires to be able to repeatedly use each device can be a time consuming and frustrating process.

It is therefore desirable to develop a method and system to organize one or more wired devices in an organized manner to substantially prevent tangling of wires.

### FIGURES

Some specific example embodiments of the disclosure may be understood by referring, in part, to the following description and the accompanying drawings.

FIG. 1A depicts a Wired Appliance Organizer (“WAO”) in accordance with an illustrative embodiment of the present disclosure disposed in a closed position.

FIG. 1B depicts a perspective view of the rear of the WAO of FIG. 1A in accordance with an illustrative embodiment of the present disclosure.

FIG. 1C depicts the WAO of FIG. 1A disposed in an open position.

FIG. 1D depicts a close up view of a rear portion of the second portion of the WAO body with the WAO body in the open position in accordance with an illustrative embodiment of the present disclosure.

FIG. 2 depicts an electrical device disposed within a holder of the WAO in accordance with an illustrative embodiment of the present disclosure in a retracted position.

FIG. 3 depicts an electrical device extended from a holder of the WAO in accordance with an illustrative embodiment of the present disclosure in a retracted position.

While embodiments of this disclosure have been depicted and described and are defined by reference to example embodiments, such references do not imply a limitation on the disclosure, and no such limitation is to be inferred. The subject matter disclosed is capable of considerable modification, alteration, and equivalents in form and function, as will occur to those skilled in the pertinent art and having the benefit of this disclosure. The depicted and described embodiments of this disclosure are examples only, and not exhaustive of the scope of the disclosure.

### DESCRIPTION

The present invention is generally directed to an improved method and system for organizing electrical appliances and more specifically, to a method and system for efficiently storing and using wired appliances.

Illustrative embodiments of the present disclosure are described in detail herein. In the interest of clarity, not all features of an actual implementation may be described in this specification. It will of course be appreciated that in the development of any such actual embodiment, numerous implementation specific decisions must be made to achieve the specific implementation goals, which will vary from one implementation to another. Moreover, it will be appreciated that such a development effort might be complex and time-consuming, but would nevertheless be a routine undertaking for those of ordinary skill in the art having the benefit of the present disclosure. To facilitate a better understanding of the present disclosure, the following examples of certain embodiments are given. In no way should the following examples be read to limit, or define, the scope of the disclosure.

The terms “couple” or “couples,” as used herein are intended to mean either an indirect or a direct connection. Thus, if a first device couples to a second device, that connection may be through a direct connection, or through an indirect connection. Similarly, when a first device is electrically coupled to a second device, the two devices may be connected through a direct or an indirect electrical connection.

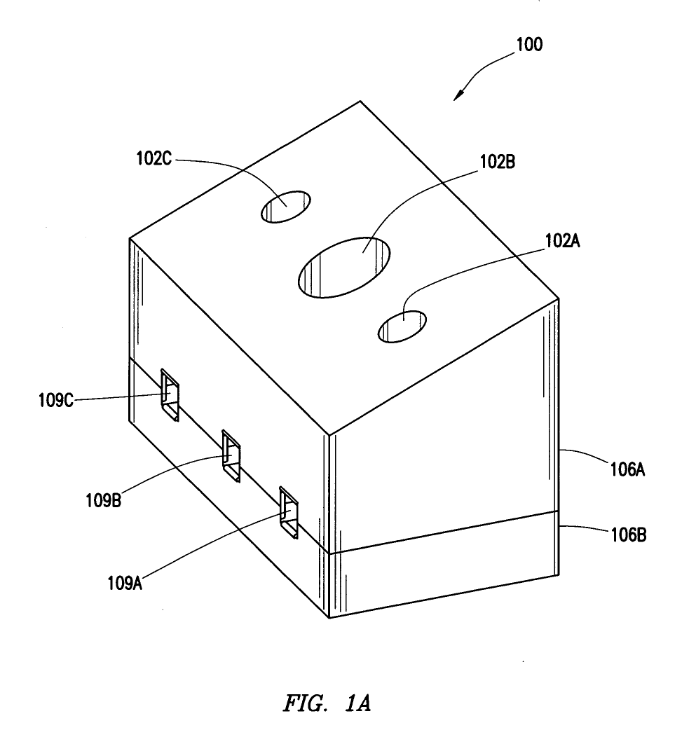

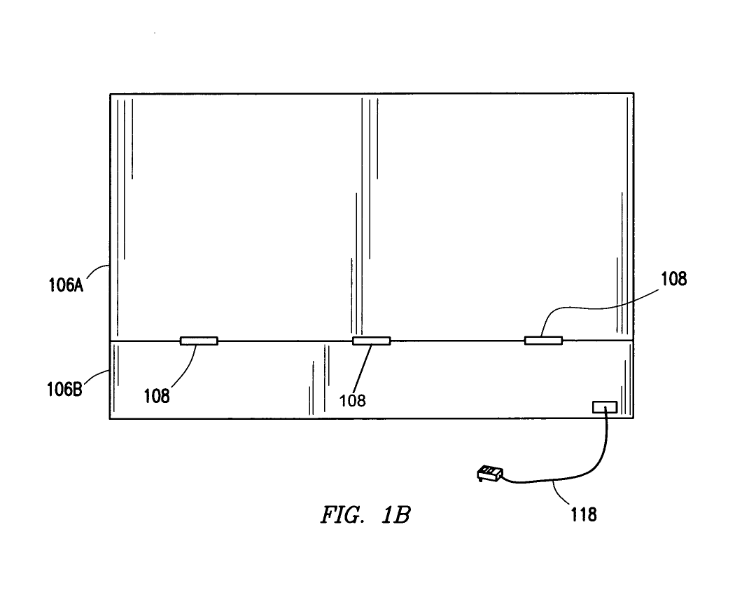

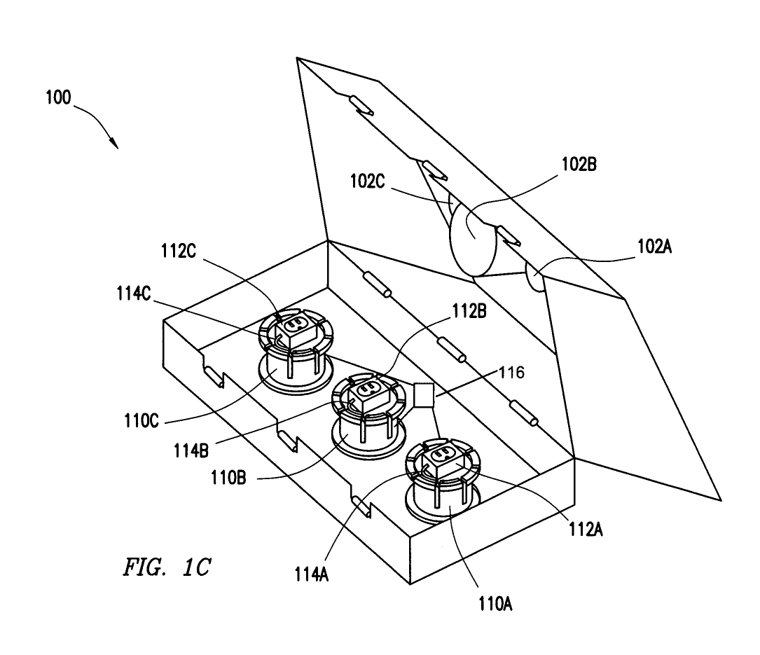

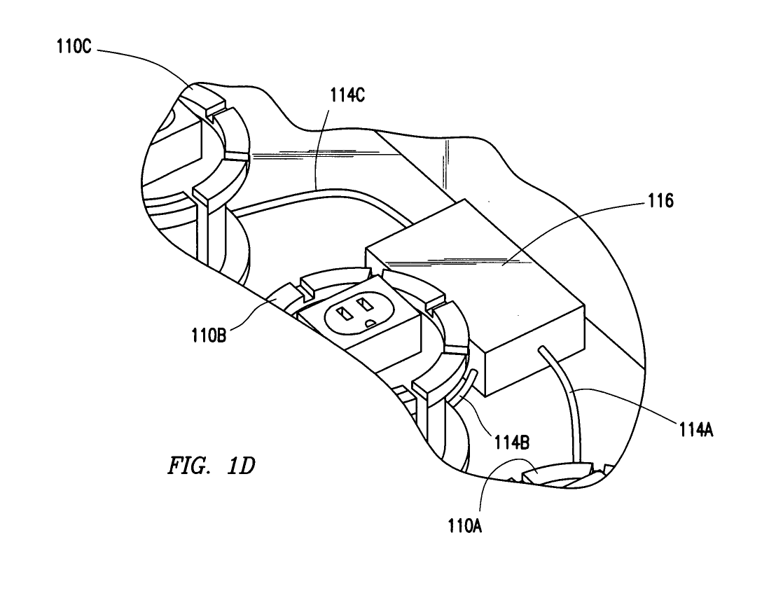

Turning now to FIG. 1A, a perspective view of a Wired Appliance Organizer (“WAO”) in accordance with an illustrative embodiment of the present disclosure is denoted generally with reference numeral 100. The WAO 100 may include one or more holders 102A-C. Although three holders 102A-C are shown in the illustrative embodiment of FIG. 1A, the present disclosure is not limited to any specific number of holders. For instance, in other embodiments, the number of holders 102 may be less than three or more than three without departing from the scope of the present disclosure. The holders 102 may be used to house the electrical devices to be organized as described in further detail below. Further, the size of the holders 102, the configuration of the holders 102 and the shape of the holders 102 may also be varied without departing from the scope of the present disclosure. For instance, the holders 102 may be circular in shape (as shown in FIG. 1A) or they may take on other shapes as desired to accommodate other electrical devices. Further, the holders 102 need not be organized linearly along the surface of the WAO 100. In other illustrative embodiments, the holders 102 may be disposed offset from one another or they may be disposed in two or more rows on the surface of the WAO 100.

In accordance with one illustrative embodiment, the WAO 100 may be used in a hair salon to organize one or more of the electrical devices used by a hair dresser. Although the present disclosure will be discussed in conjunction with utilization of the WAO 100 in a hair salon, the present invention is not limited to this particular implementation. Specifically, the methods and systems disclosed herein may be used to organize any other electrical devices in other settings without departing from the scope of the present disclosure. For instance, the WAO 100 may be used to organize electrical devices in a garage, in the kitchen, in a household bathroom, or in any other domestic or industrial settings. Accordingly, the discussion of the WAO 100 in conjunction with its use in a hair salon is provided as one exemplary application.

Returning to FIG. 1A, one electrical device may be placed each of the holders 102A, 102B, 102C. The holders 102A-C may be formed in the WAO 100 body 106. Specifically, the body 106 may include a first portion 106A and a second portion 106B which can be selectively moved to configure the body 106 in a closed position and an open position as described in further detail below. In the illustrative embodiment of FIGS. 1A-C, the first portion 106A includes the holders 102A-C and is movable relative to the second portion 106B which may rest on a surface such as, for example, a counter or a table top.

In certain implementations, the holders 102A-C may be made from or lined with a heat resistant material in order to be able to house a hot electrical device such as a curling iron or a hair straightener immediately after it has been used. Alternatively, the holders 102A-C may be designed so that they can house one or more removable inserts (not shown), each suited for a particular electrical device. In this manner, a user may arrange the inserts (not shown) in the holders 102A-C in a configuration that is best suited for the particular application. For instance, in certain illustrative embodiments, the holders 102A-C may be lined with stainless steel or any other suitable materials known to those of ordinary skill in the art, having the benefit of the present disclosure.

The cross-section of the body 106 may take on any suitable shape without departing from the scope of the present disclosure. For instance, in one illustrative embodiment, the body 106 may be cubic. In another embodiment, the body 106 may be designed so it has a trapezoidal cross-section (as shown in FIG. 1A), a circular cross-section or a rectangular cross-section. Specifically, the shape of the body 106 may be adjusted to meet the user's demand and space availability. Further, the body 106 may be made of any suitable materials known to those of ordinary skill in the art, having the benefit of the present disclosure. For instance, in certain illustrative embodiments, the body 106 may be made of metal, stainless steel, wood or fiberglass. Further, in certain embodiments, the body 106 may be enclosed in a leather outer layer or other desirable materials to render the WAO 100 aesthetically appealing.

The body 106 may further include one or more inlets 109A, 109B, 109C, disposed at an interface between the first portion 106A and the second portion 1068 of the body 106. Each inlet 109A-C may be associated with a corresponding holder 102A, 102B, 102C. As discussed in further detail below, each inlet 109A, 109B, 109C may be used to facilitate electrical connection of a corresponding electrical device that is housed in one of the holders 102A, 102B, 102C to a corresponding reel 110A-C. Specifically, an electrical device may be disposed in a holder 102A-C and the power supply wire from the electrical device may be directed to the corresponding reel 110A-C located within the body 106 through the inlets 109A-C.

FIG. 1B depicts a perspective view of the rear of the WAO 100 in accordance with an illustrative embodiment of the present disclosure. The body 106 may further include one or more hinges 108 at an interface between the first portion 106A and the second portion 106B. The hinges 108 permit the body 106 to be configured in an open position and a closed position as shown in FIGS. 1A and 1C, respectively.

Specifically, FIG. 1A depicts the WAO 100 with the body 106 in its closed position. In contrast, FIG. 1C depicts the WAO 100 with the body flipped open along the hinges 108. As shown in FIG. 1C, the WAO 100 may include one or more reels 110A-C disposed within the body 106. Each reel 110A-C may be associated with a corresponding holder 102A-C. For instance, in the illustrative embodiment of FIGS. 1A and 1C, the WAO 100 includes three reels 110A-C, each associated with one of the holders 102A-C. However, as would be appreciated by those of ordinary skill in the art, having the benefit of the present disclosure, the present disclosure is not limited to any specific number of holders 102 or reels 110. Accordingly, any number of holders 102 and reels 110 may be used without departing from the scope of the present disclosure.

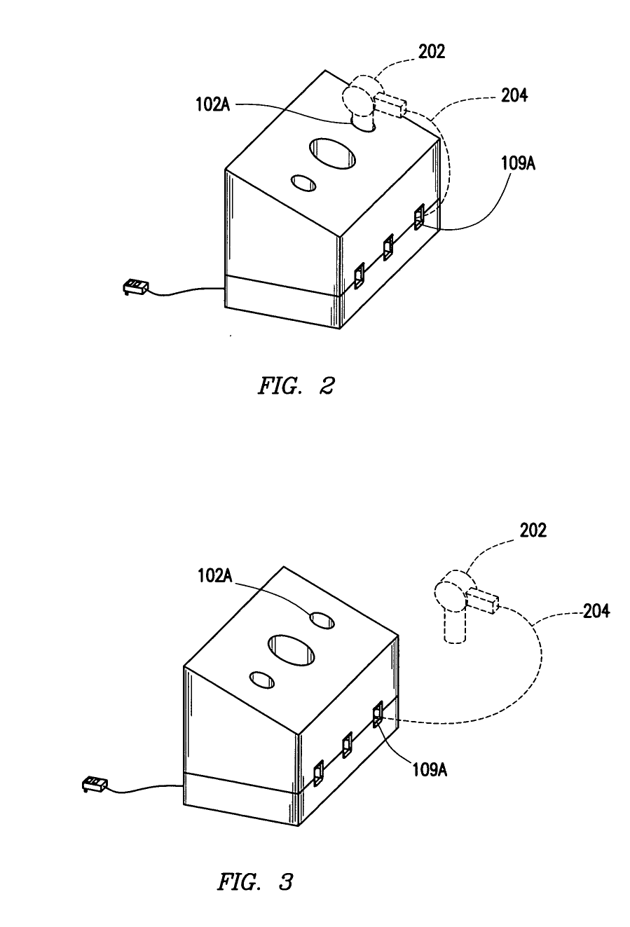

Further, in certain illustrative embodiments, the reels 110A-C may be biased to return to their wound up position as discussed in further detail below. For instance, in one embodiment, the reels 110A-C may be spring biased, although other mechanisms may be used to bias the reels 110A-C without departing from the scope of the present disclosure. The operation of the reels 110A-C is discussed in further detail in conjunction with FIGS. 2A and 2B, below.

Each reel 110A-C includes a corresponding electrical outlet 112A-C and a corresponding power supply wire 114A-C. The power supply wires 114A-C from the different reels 110A-C may be electrically coupled to a main power supply line 118. In one illustrative embodiment, the connection may be made through a junction box 116.

FIG. 1D depicts a close up view of a rear portion of the second portion 106B of the WAO body 106 with the WAP 100 in the open position. As shown in FIG. 1D, in certain illustrative embodiments, a junction box 116 may be disposed within the WAO 100. As shown in FIG. 1D, each power supply wire 114A-C may then be directed to the junction box 116 and coupled to the main power supply line 118 therein. The main power supply line 118 may be used to couple the WAO 100 to a single electrical socket (not shown) such as a traditional wall socket.

FIGS. 2 and 3 depict an electrical device coupled to the WAO 100 in a retracted position and in an extended position, respectively. Specifically, as shown in FIGS. 2 and 3, any wired electrical device such as, for example, a blow dryer 202 may be disposed within a holder 102 or extended from the holder 102 when in use. In each instant, the WAO 100 insures that the power supply line 204 of the electrical device 202 remains organized as discussed in further detail below. The wired electrical device 202 may be any suitable device, without departing from the scope of the present disclosure and is not limited to a blow dryer to or any particular type of electrical device.

The operation of the WAO 100 is now discussed in further detail in conjunction with utilizing the electrical device 202.

As shown in FIG. 1C, the WAO 100 is first flipped open along the hinges 108. Next the power supply line 204 of the electrical device 202 is wound around a reel 110A associated with a desired holder 102A where the electrical device 202 is to be housed. Specifically, the user first determines the position of which holder 102A-C is best suited for the particular electrical device. Once a holder 102A-C is selected, the user will wind the power supply line 204 of the electrical device 202 around the reel 110 corresponding to that particular holder 102. In the illustrative embodiment of FIG. 2, it is assumed that it is desirable to install the electrical device 202 into the holder 102A. Accordingly, the user winds the power supply line 204 of the electrical device 202 around the reel 110A and connects the terminal end of the power supply line 204 of the electrical device 202 it to the reel's 110A electrical outlet 112A. As previously noted, and shown in FIG. 1D, the electrical outlet 112A is electrically coupled to the main power supply line 118 through the junction box 116. Accordingly, once the main power supply line 118 is connected to a wall socket or other power source, power is delivered through the power supply wire 114 to the electrical device 202 and the electrical device 202 is ready for operation.

Next, the user can flip the WAO 100 to its closed position along the hinges 108 as shown in FIG. 1A (as well as FIGS. 2 and 3). With the WAO 100 closed, the power supply line 204 extends from the inside of the WAO 100 through the inlet 109A corresponding to the reel 110A. Because the reel 110A is biased, it will maintain the power supply line 204 in its wound up position inside the WAO 100, until the user pulls on the power supply line 204 by moving the electrical device 202 away from the WAO 100 as shown in FIG. 3. Accordingly, as shown in FIG. 3, with the WAO 100 body 106 closed, the user can move the electrical device 202 into an extended position. Specifically, the user may pull the electrical device 202 away from the WAO 100, extending the power supply line 204 out of the reel 110A. However, once the user has completed the task at hand, and moves the electrical device close to the WAO 100, the reel 110A will automatically turn, winding up the power supply line 204 around the reel 110A as the electrical device 202 is moved closer to the holder 102A. As shown in FIG. 2, the user can then simply place the electrical device 202 in the designated holder 102A where it will remain, until the next time it is needed.

Additional wired electrical devices (not shown) may be similarly installed in the remaining holders 102B, 102C using the WAO 100. Consequently, the WAO 100 permits the user to organize multiple wired electrical devices and use them in any order and with any frequency without having to be concerned about organizing the electrical devices or detangling the power supply lines 204 associated with the different electrical devices.

Accordingly, the WAO 100 provides a mechanism that organizes wired electrical devices, saves space, and permits easy retrieval and use of the devices. Further, the electrical devices may be easily retrieved, used and placed back in their designated position without the need for an operator to detangle the wires or otherwise spend time organizing the electrical devices.

Therefore, the present invention is well-adapted to carry out the objects and attain the ends and advantages mentioned as well as those which are inherent therein. While the invention has been depicted and described by reference to exemplary embodiments of the invention, such a reference does not imply a limitation on the invention, and no such limitation is to be inferred. The invention is capable of considerable modification, alteration, and equivalents in form and function, as will occur to those ordinarily skilled in the pertinent arts and having the benefit of this disclosure. The depicted and described embodiments of the invention are exemplary only, and are not exhaustive of the scope of the invention. Consequently, the invention is intended to be limited only by the spirit and scope of the appended claims, giving full cognizance to equivalents in all respects. The terms in the claims have their plain, ordinary meaning unless otherwise explicitly and clearly defined by the patentee.

What is claimed is:

1. A wired appliance organizer comprising:
a body configurable in an open position and a closed position;
a holder disposed within the body;
a reel disposed within the body, wherein the reel comprises an electrical outlet;
a power supply wire, wherein the power supply wire electrically couples the electrical outlet to a main power supply line; and
an inlet, wherein a power supply wire from an electrical device is directed into the body through the inlet.

2. The wired appliance organizer of claim I, wherein the reel is biased.

3. The wired appliance organizer of claim 1, wherein there reel is spring loaded.

4. The wired appliance organizer of claim 1, wherein the holder comprises an insert.

5. The wired appliance organizer of claim 4, wherein the insert is lined with a heat resistant material.

6. The wired appliance organizer of claim 1, further comprising a junction box disposed within the body, wherein the power supply wire is coupled to the main power supply line within the junction box.

7. The wired appliance organizer of claim I, wherein the body comprises a first portion and a second portion, wherein the holder is disposed within the first portion of the body and the reel is disposed within the second portion of the body.

8. A method of organizing one or more electrical devices comprising:
moving a first portion of a body of a wired appliance organizer relative to a second portion of the body of the wired appliance organizer to configure the wired appliance organizer in an open position;
winding a power supply line of an electrical device around a reel disposed within the body of the wired appliance organizer;
connecting the power supply line of the electrical device to an electrical outlet corresponding to the reel;
moving the first portion of the body of the wired appliance organizer relative to the second portion of the body of the wired appliance organizer to configure the wired appliance organizer in a closed position; and
selectively moving the electrical device between a first extended position away from the body of the wired appliance organizer and a second retracted position within the body of the wired appliance organizer.

9. The method of claim 8, wherein in the second retracted position the electrical device is positioned in a holder disposed within the body of the wired appliance organizer.

10. The method of claim 9, further comprising disposing an insert within the holder, wherein the electrical device is positioned within the insert.

11. The method of claim 10, wherein the insert is heat resistant.

12. The method of claim 8, further comprising biasing the reel, wherein the reel winds up the power supply line of the electrical device as the electrical device moves towards the wired appliance organizer.

13. The method of claim 13, wherein biasing the reel comprises spring loading the reel.

14. A wired appliance organizer comprising:
a body having a first portion and a second portion;
a plurality of holders disposed within the first portion;
a plurality of reels disposed within the second portion,
wherein each of the plurality of reels corresponds to one of the plurality of holders,
wherein each of the plurality of reels comprises an electrical outlet coupled to a power supply wire, and
wherein each power supply wire is coupled to a main power supply line.

15. The wired appliance organizer of claim 14, wherein a junction box couples each power supply wire to the main power supply line.

16. The wired appliance organizer of claim 14, wherein at least one of the reels is biased.

17. The wired appliance organizer of claim 14, wherein at least one of the reels is spring loaded.

18. The wired appliance organizer of claim 14, wherein at least one of the holders is lined with a heat resistant material.

19. The wired appliance organizer of claim 14, further comprising a plurality of inlets disposed at an interface between the first portion and the second portion of the body.

20. The wired appliance organizer of claim 14, further comprising one or more hinges at an interface between the first portion and the second portion of the body.
